(19) United States
(12) Patent Application Publication
(10) Pub. No.: US 2007/0120230 A1
(43) Pub. Date: May 31, 2007

(54) Layer structure, method of forming the layer structure, method of manufacturing a capacitor using the same and method of manufacturing a semiconductor device using the same

(75) Inventors: Shin-Hye Kim, Suwon-si (KR); Ju-Bum Lee, Hwaseong-gun (KR); Do-Hyung Kim, Uijeongbu-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/585,083

(22) Filed: Oct. 24, 2006

(30) Foreign Application Priority Data
Nov. 30, 2005 (KR) 10-2005-0115318

(51) Int. Cl. H01L 21/8242; H01L 21/20; H01L 23/58; H01L 21/31

(52) U.S. Cl. 257/645; 438/786; 438/396; 438/253; 257/E21.278

(57) ABSTRACT

In a layer structure, a method of forming the layer structure, a method of manufacturing a capacitor having the layer structure and a method of manufacturing a semiconductor device having the capacitor, a structure may be formed on a substrate. A first insulation layer including at least one kind of impurities may be formed on the structure. A flatness of the first insulation layer may fluctuate according to the type and concentration of the impurities. The first insulation layer may include silicate glass doped with first impurities including an element in Group III and/or second impurities including an element in Group V. The flatness of the first insulation layer may improve in proportion to the concentration of the first impurities whereas in inverse proportion to the concentration of the second impurities. Accordingly, the flatness of the first insulation layer may be determined by adjusting the type and concentration of the impurities.

### PRIORITY STATEMENT

This application claims priority under 35 USC § 119 to Korean Patent Application No. 2005-115318, filed on Nov. 30, 2005, in the Korean Intellectual Property Office (KIPO), the entire contents of which are herein incorporated by reference.

### BACKGROUND

1. Field

Example embodiments relate to a layer structure, a method of forming the layer structure, a method of manufacturing a capacitor having the layer structure and a method of manufacturing a semiconductor device having the capacitor.

2. Description of the Related Art

A semiconductor device (e.g., a dynamic random access memory (DRAM) device) may be used to memorize information (e.g., data and/or program commands). The information may be inputted in or outputted from the semiconductor device. In order to perform these functions, various semiconductor devices (e.g., a gate structure, a transistor and/or a capacitor) may be formed on a semiconductor substrate.

As an integration degree of the semiconductor device increases, an area per a unit memory cell may decrease. In a highly integrated semiconductor device (e.g., the gate structure), the transistor and the capacitor may be formed on the semiconductor substrate so that a cell area in which a semiconductor device is formed may be decreased. A planarizing process of an insulation layer covering structures on the semiconductor substrate may be required in order to form another structure. The planarizing process may serve to reduce a height difference between structures on the semiconductor substrate. When the insulation layer is not uniformly formed, the height difference between the structures may be accumulated so that performing a photolithography process may lose its significance. A hole may not be properly formed through the insulation layer.

When the capacitor is formed, a structure of the capacitor is fluctuated from a flattened shape to a relatively complicated shape (e.g., a box and/or a cylindrical shape) so as to gain a higher capacitance. In the semiconductor device having a line width of less than about 0.1 μm, an aspect ratio of the capacitor may increase in order to gain the higher capacitance. In order to form the capacitor having a relatively high aspect ratio, an insulation layer and/or a mold layer for forming a lower electrode of the capacitor may be highly and uniformly formed. Otherwise, a 2-bit fail may occur between adjacent lower electrodes.

FIGS. 1A and 1B are diagrams illustrating a conventional method of forming a capacitor. Referring to FIG. 1A, an insulating interlayer 10 may be formed on a semiconductor substrate (not shown). A contact hole may be formed in the insulating interlayer 10. The contact hole may expose a contact region (not shown) in the semiconductor substrate. A pad 15 may be formed in the insulating interlayer 10 to fill the contact hole. An etch stop layer 20 may be formed on the pad 15 and the insulating interlayer 10. The etch stop layer 20 may be formed using a nitride.

A lower insulation layer 25 and an upper insulation layer 30 may be successively formed on the etch stop layer 20. The lower insulation layer 25 may be formed using a material having an etching rate faster than that of the upper insulation layer 30 with respect to an etching solution including hydrogen fluoride (HF). For example, when the lower insulation layer 25 is formed using boron phosphorus silicate glass (BPSG) and/or phosphorus silicate glass (PSG), the upper insulation layer 30 may be formed using undoped silicate glass (USG), tetraethyl orthosilicate (TEOS), plasma enhanced-tetraethyl orthosilicate (PE-TEOS) and/or high density plasma-chemical vapor deposition (HDP-CVD) oxide. A mask layer 35 may be formed on the upper insulation layer 30. A photoresist pattern (not shown) may be formed on the mask layer 35.

As mentioned above, the lower insulation layer 25 may be formed using a material having an etching selectivity relative to the upper insulation layer 30 with respect to an etching solution including hydrogen fluoride. BPSG may be used as a proper material for forming the lower insulation layer 25. When the lower insulation layer 25 is formed using BPSG, the lower insulation layer 25 may have a deteriorated flatness. The deteriorated flatness of the lower insulation layer 25 may influence the lower electrode 30, the mask layer 35 and the photoresist pattern.

Referring to FIG. 1B, the mask layer 35, the upper electrode 30, the lower electrode 25 and the etch stop layer 20 may be successively patterned to form a hole 40 exposing the pad 15. The deteriorated flatness of the lower insulation layer 25 may influence the lower electrode 30, the mask layer 35 and the photoresist pattern as shown in FIG. 1B, so that a leaning defect may occur causing adjacent holes 40 to make contact with each other. The leaning defect may induce the 2-bit fail between adjacent capacitors.

In order to improve a flatness of the lower insulation layer 25, performing an additional process (e.g., a wet re-flow process and/or a chemical mechanical polishing (CMP) process) has been suggested. The additional process may increase processing time and costs. As the re-flow process and/or the CMP process may damage a lower structure, a method of improving the flatness of the lower insulation layer 25 without damage may be required.

### SUMMARY

Example embodiments provide a layer structure including an insulation layer having an improved flatness and a method of forming a layer structure including an insulation layer having an improved flatness. Example embodiments also provide a method of forming a capacitor having the layer structure and a method of forming a semiconductor device having the capacitor.

According to example embodiments, a layer structure may include a first insulation layer formed on a structure. The first insulation layer may include at least one kind of impurities and a flatness of the first insulation layer may be adjusted according to the type and concentration of the impurities.

In example embodiments, the first insulation layer may include an oxide doped with first impurities including an element in Group III. The flatness of the first insulation layer may improve in proportion to a concentration of the first impurities. The first impurities may include boron (B). The first insulation layer may further include second impurities including an element in Group V. The flatness of the first insulation layer may improve in inverse proportion to a concentration of the second impurities. The second impurities may include phosphorus (P) or arsenic (As). The structure may include a conductive structure and/or an insulation structure formed on a substrate.

According to example embodiments, a method of forming a layer structure may include forming a structure on a substrate. A first insulation layer may be formed on the structure. The first insulation layer may include at least one kind of impurities and a flatness of the first insulation layer may vary according to the type and concentration of the impurities. An oxide layer may be formed on the structure. First impurities including an element in Group III may be doped into the oxide layer.

In example embodiments, forming the oxide layer and doping the first impurities may be simultaneously performed. The oxide layer may be formed by supplying a first source gas including an ozone (O₃) gas and a silane (SiH₄) gas. The first impurities may be doped by supplying a second source gas including triethylborate (TEB) into the oxide layer. The oxide layer may be formed on the structure. First impurities including an element in Group III may be doped into the oxide layer. Second impurities including an element in Group V may be doped into the oxide layer. Doping the first impurities and doping the second impurities may be simultaneously performed.

In example embodiments, the oxide layer may be formed by supplying a first source gas including an ozone gas and a silane gas. The first impurities may be doped by supplying a second source gas including triethylborate (TEB) into the oxide layer. The second impurities may be doped by supplying a third source gas including triethylphosphate (TEPO) into the oxide layer. A flow rate ratio between the second source gas and the third source gas may be in a range of about 1.0:0.1 to about 1.0:5.5. A flow rate ratio between the second source gas and the third source gas may be in a range of about 1.0:0.1 to about 1.0:1.0.

According to example embodiments, a method of forming a capacitor may include forming the layer structure according to example embodiments on a substrate. A second insulation layer may be formed on the first insulation layer. The first and the second insulation layers may be partially etched to thereby form a hole in the first and the second insulation layers. A conductive layer may be formed in the hole. The conductive layer on the second insulation layer may be removed. The first and the second insulation layers may be removed to form a lower electrode.

In example embodiments, an oxide layer may be formed on the substrate. First impurities including an element in Group III may be doped into the oxide layer. Forming the oxide layer and doping the first impurities may be simultaneously performed. The oxide layer may be formed by supplying a first source gas including an ozone gas and a silane gas. The first impurities may be doped by supplying a second source gas including triethylborate into the oxide layer. The oxide layer may be formed on the substrate. First impurities including an element in Group III may be doped into the oxide layer. Second impurities including an element in Group V may be doped into the oxide layer. Doping the first impurities and doping the second impurities may be simultaneously performed.

In example embodiments, the oxide layer may be formed by supplying a first source gas including an ozone gas and a silane gas. The first impurities may be doped by supplying a second source gas including triethylborate into the oxide layer. The second impurities may be doped by supplying a third source gas including triethylphosphate into the oxide layer. A flow rate ratio between the second source gas and the third source gas may be in a range of about 1.0:0.1 to about 1.0:5.5. The first insulation layer may be formed using a material having an etching selectivity of about 2:1 to about 5:1 relative to the second insulation layer when an etching solution including hydrogen fluoride (HF) is used for etching the first and the second insulation layers.

In example embodiments, the second insulation layer may be formed using tetraethyl orthosilicate (TEOS), plasma enhanced-TEOS (PE-TEOS), high density plasma-CVD (HDP-CVD) oxide, undoped silicate glass (USG) and/or spin on glass (SOG). A dielectric layer and an upper electrode may be additionally formed on the lower electrode. An etch stop layer may be additionally formed on the substrate before forming the first insulation layer.

According to example embodiments, a method of forming a semiconductor device may include forming a contact region on a substrate. A conductive structure may be formed on the substrate. An insulating interlayer may be formed on the conductive structure. A pad making contact with the contact region may be formed through the insulating interlayer. A capacitor according to example embodiments may be formed on the pad and the insulating interlayer. A dielectric layer and an upper electrode may be formed on the lower electrode.

In example embodiments, the insulating interlayer may include an oxide doped with at least one kind of impurities and a flatness of the insulating interlayer may vary according to the type and concentration of the impurities. An oxide layer may be formed on the insulating interlayer. First impurities including an element in Group III may be doped into the oxide layer. The oxide layer may be formed by supplying a first source gas including an ozone gas and a silane gas. The first impurities may be doped by supplying a second source gas including triethylborate into the oxide layer. The oxide layer may be formed on the insulating interlayer. First impurities including an element in Group III may be doped into the oxide layer. Second impurities including an element in Group V may be doped into the oxide layer.

In example embodiments, the oxide layer may be formed by supplying a first source gas including an ozone gas and a silane gas. The first impurities may be doped by supplying a second source gas including triethylborate into the oxide layer. The second impurities may be doped by supplying a third source gas including triethylphosphate into the oxide layer. In example embodiments, a flow rate ratio between the second source gas and the third source gas may be in a range of about 1.0:0.1 to about 1.0:5.5. The first insulation layer may be formed using a material having an etching selectivity of about 2:1 to about 5:1 relative to the second insulation layer when an etching solution including hydrogen fluoride is used for etching the first and the second insulation layers. The second insulation layer may be formed using TEOS, PE-TEOS, HDP-CVD oxide, USG and/or SOG. An etch stop layer may be further formed on the insulating interlayer before forming the first insulation layer.

According to example embodiments, a flatness of an insulation layer may fluctuate according to the type and concentration of doped impurities. The insulation layer may be formed by doping with first impurities including an element in Group III (e.g., boron (B)) into silicate glass. The insulation layer may be also formed by doping with the first impurities including the element in Group III (e.g., boron (B)) and second impurities including an element in Group V (e.g., phosphorus (P) and/or arsenic (As)) into silicate glass. The flatness of the insulation layer may improve in proportion to the concentration of the first impurities and in inverse proportion to the concentration of the second impurities. Accordingly, the flatness of the insulation layer may be controlled by changing the type and the concentration of the impurities so that an additional process (e.g., a CMP process and/or a re-flow process) may not be required after forming the insulation layer.

### BRIEF DESCRIPTION OF THE DRAWINGS

Example embodiments will be more clearly understood from the following detailed description taken in conjunction with the accompanying drawings. FIGS. 1A-9F represent non-limiting, example embodiments as described herein.

FIGS. 1A and 1B are diagrams illustrating a conventional method of forming a capacitor;

FIG. 2 is a diagram illustrating a layer structure in accordance with example embodiments;

FIGS. 3A to 3B are diagrams illustrating a method of forming a layer structure in accordance with example embodiments;

FIG. 4 is a graph illustrating a result of measuring a flatness of an insulation layer in a layer structure formed according to Examples 1 to 6 and Comparative Examples 1 to 4;

FIG. 5 is an atomic force microscopic picture illustrating a surface of an insulation layer according to Example 1;

FIG. 6 is an atomic force microscopic picture illustrating a surface of an insulation layer according to Comparative Example 5;

FIGS. 7A to 7D are diagrams illustrating a method of manufacturing a capacitor in accordance with example embodiments;

FIG. 8 is a graph illustrating a result of measuring numbers of leaning defects of a capacitor according to Examples 2 to 6 and Comparative Examples 1 to 4; and

FIGS. 9A to 9F are diagrams illustrating a method of manufacturing a semiconductor device in accordance with example embodiments.

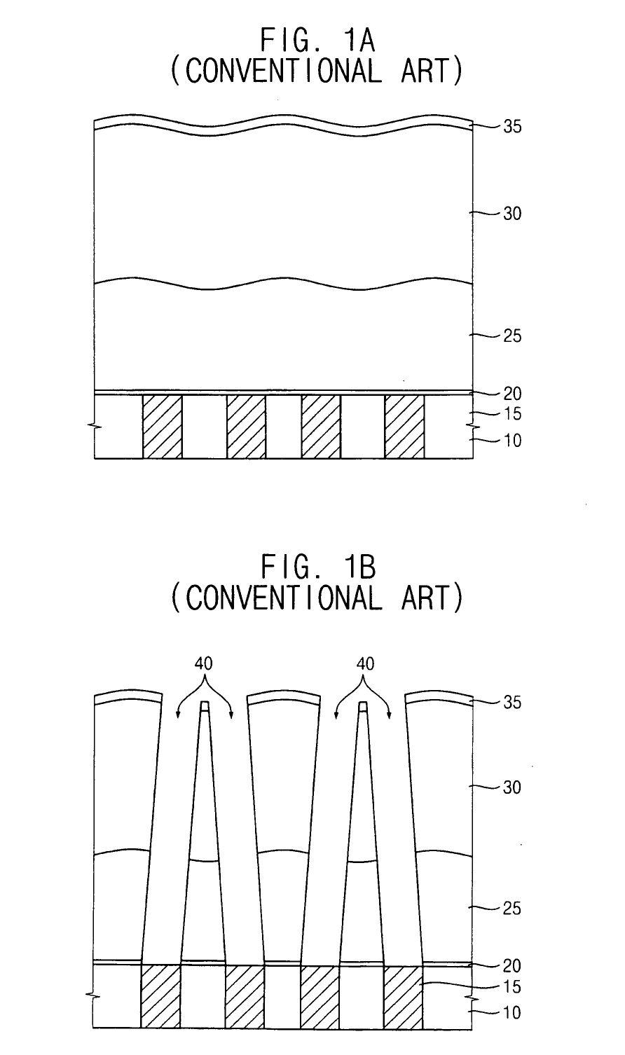

### DETAILED DESCRIPTION OF EXAMPLE EMBODIMENTS

Example embodiments are described more fully hereinafter with reference to the accompanying drawings, in which example embodiments are shown. Example embodiments may, however, be embodied in many different forms and should not be construed as limited to the example embodiments set forth herein. Rather, these embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that “layer structure” and “structure” do not necessarily represent the same structure and that the terms used to describe a structure and/or layer structure do not limit the scope of the example embodiments of a layer structure and/or structure.

Layer Structure and Method of Forming the Layer Structure

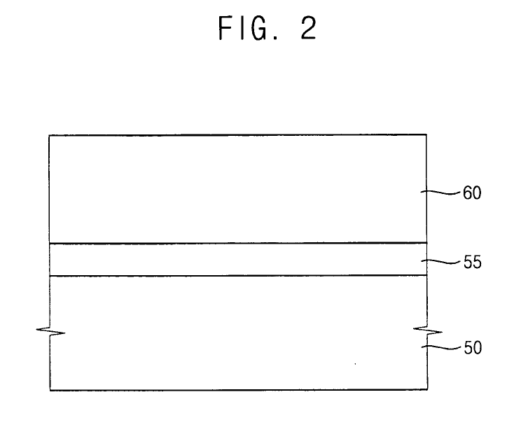

FIG. 2 is a diagram illustrating a layer structure in accordance with example embodiments. Referring to FIG. 2, a first insulation layer 60 may be formed on a substrate 50 to cover a structure 55. The substrate 50 may include a silicon wafer, a silicon-on-insulator (SOI) substrate and/or a single crystalline metal oxide substrate. The structure 55 may be formed on the substrate 50. The structure 55 may include a conductive structure (e.g., a contact region, a pad, a plug, an electrode, a conductive wiring, a conductive pattern, a gate structure and/or a transistor). The structure 55 may include an insulation structure (e.g., an insulating interlayer, an etch stop layer, a spacer and/or a mask layer).

The first insulation layer 60 may include an oxide (e.g., silicon oxide doped with impurities). A flatness of the first insulation layer 60 may be varied according to the type and concentration of impurities doped therein. When first impurities including an element Group III are doped into the first insulation layer 60, the flatness of the first insulation layer 60 may improve in proportion to a concentration of the first impurities. When second impurities including an element in Group V are doped into the first insulation layer 60, the flatness of the first insulation layer 60 may improve in inverse proportion to the concentration of the second impurities. When the first impurities including the element in Group III and the second impurities including the element in Group V are both doped into the first insulation layer 60, the flatness of the insulation layer 60 may be in a predetermined or given range according to the concentrations of the first and the second impurities. In some example embodiments, a first concentration of the first impurities may be greater than a second concentration of the second impurities. For example, a ratio between the first concentration and the second concentration may be in a range of about 1.0:0.1 to about 1.0:1.0.

In example embodiments, the first insulation layer 60 may include silicate glass doped with the first impurities including the element in Group III. For example, the first impurities may include boron (B). The first insulation layer 60 may include silicate glass doped with the first impurities including the element in Group III the second impurities including the element in Group V. For example, the first impurities may include boron (B) and the second impurities may include phosphorus (P) and/or arsenic (As).

The flatness of the first insulation layer 60 may improve in proportion to the first concentration of the first impurities including the element in Group III and in inverse proportion to the second concentration of the second impurities including the element in Group V. As the first concentration of the first impurities increases, the flatness of the first insulation layer 60 may improve. As the second concentration of the second impurities decreases, the flatness of the first insulation layer 60 may improve. The flatness of the first insulation layer 60 may improve by adjusting the concentrations of the first and the second impurities.

The flatness of the first insulation layer 60 may have an influence upon the flatness of upper structures formed on the first insulation layer 60 (e.g., another insulation layer, an etch stop layer, a mask pattern and/or a photoresist pattern). When the first insulation layer 60 has a flat surface, the upper structures may also have flat surfaces. On the other hand, when the first insulation layer 60 has a rough surface, the upper structures may also have rough surfaces. In example embodiments, because the flatness of the first insulation layer 60 may improve by adjusting the types and the concentrations of the impurities doped into the first insulation layer 60, the flatness of the upper structures may also be improved by adjusting the types and the concentrations of the impurities doped into the first insulation layer 60. According to some example embodiments, the first insulation layer 60 may be employed to various structures having flat surface. For example, the first insulation layer 60 may be applied as a gate oxidation layer of a transistor, an insulating interlayer, a mask layer and/or a sacrificial layer in a semiconductor device.

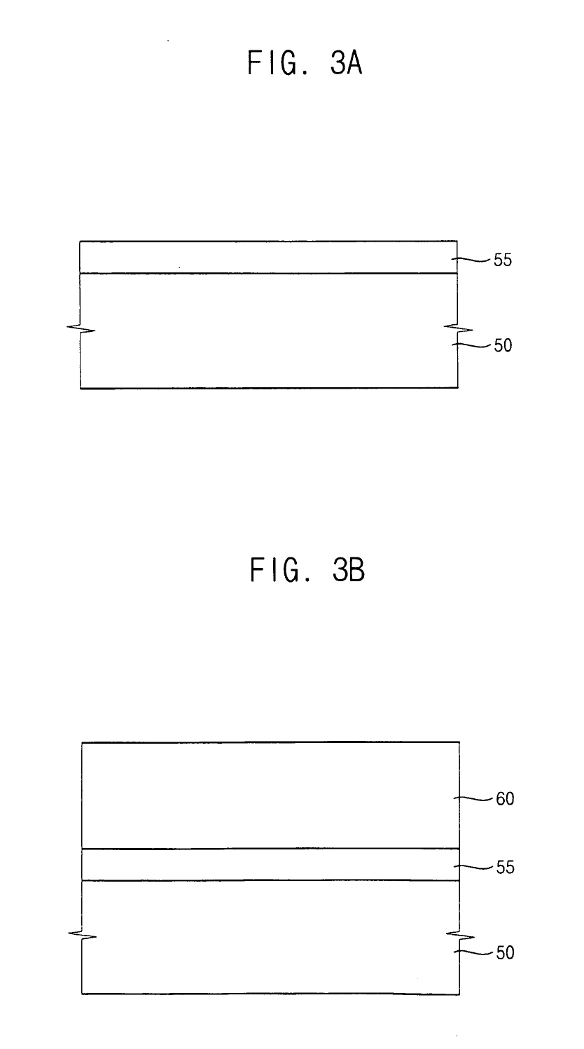

FIGS. 3A to 3B are diagrams illustrating a method of forming a layer structure in accordance with example embodiments. Referring to FIG. 3A, a structure 55 may be formed on a substrate 50. The substrate 50 may include a silicon wafer, an SOI substrate and/or a single crystalline metal oxide substrate. The structure 55 may include a conductive structure (e.g., a contact region, a pad, a plug, an electrode, a conductive wiring, a conductive pattern, a gate structure and/or a transistor). The structure 55 may include an insulating structure (e.g., an insulating interlayer, an etch stop layer, a spacer and/or a mask layer).

Referring to FIG. 3B, a first insulation layer 60 may be formed on the structure 55. In example embodiments, the first insulation layer 60 may include an oxide (e.g., silicon oxide doped with impurities). A flatness of the first insulation layer 60 may fluctuate according to the type or concentration of doped impurities. For example, the flatness of the first insulation layer 60 may be improved in proportion to the concentration of first impurities including an element in Group III and in inverse proportion to the concentration of second impurities including an element in Group V. In example embodiments, the first insulation layer 60 may be formed by doping silicate glass with the first impurities including the element in Group III. The first insulation layer 60 may be formed by doping silicate glass with the first impurities including the element in Group III and the second impurities including an element in Group V. For example, the first impurities may include boron (B) and the second impurities may include phosphorus (P) and/or arsenic (As).

The first insulation layer 60 may be employed as structures having flat surfaces. For example, the first insulation layer 60 may be applied as a gate oxidation layer of a transistor, an insulating interlayer, a mask layer and/or a sacrificial layer in a semiconductor device. The first insulation layer 60 may be applied as a mold layer for forming a lower electrode of a capacitor. In example embodiments, the first insulation layer 60 may be employed as an insulating interlayer in a semiconductor device. The first insulation layer 60 may be formed by a chemical vapor deposition (CVD) process, a plasma enhanced chemical vapor deposition (PECVD) process, a high density plasma-chemical vapor deposition (HDP-CVD) process and/or an atomic layer deposition (ALD) process.

When the first insulation layer 60 is formed by a CVD process, a silicon oxide layer may be formed using a first source gas including an ozone (O₃) gas and a silane (SiH₄) gas. The first impurities including boron are doped into the silicon oxide layer using a second source gas including triethylborate (TEB). The first impurities including boron and the second impurities including phosphorus are doped into the silicon oxide layer using the second source gas including triethylborate and a third source gas including triethylphosphate (TEPO). A flow rate ratio between the second source gas and the third source gas may be in a range of about 1.0:0.1 to about 1.0:5.5. For example, the second source gas may be supplied at a flow rate of less than about 320 sccm and the third source gas may be supplied at a flow rate of less than about 240 sccm. The flow rate ratio between the second source gas and the third source gas may be in a range of about 1.0:0.1 to about 1.0:1.0, for example, in a range of about 1.0:0.1 to about 1.0:0.5. For example, the second source gas may be supplied at the flow rate of about 160 sccm to about 280 sccm, and the third source gas may be supplied at the flow rate of about 30 sccm to about 120 sccm. When the second source gas is supplied at the flow rate greater than that of the third source gas, the flatness of the first insulation layer 60 may improve.

Measurement of Characteristics of a Layer Structure

Characteristics of a layer structure of example embodiments will be further described with reference to various Examples and Comparative Examples.

### EXAMPLE 1

An insulating interlayer was formed on a substrate to cover a lower structure formed on the substrate. An etch stop layer was formed on the insulating interlayer using silicon nitride. An insulation layer was formed on the etch stop layer by a chemical vapor deposition (CVD) process using silicon oxide doped with first impurities including boron (B). A source gas including triethylborate (TEB) was supplied at a flow rate of about 456 sccm in order to dope the silicon oxide with the first impurities.

### EXAMPLE 2

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron. A source gas including TEB was supplied at a flow rate of about 320 sccm in order to dope the silicon oxide with the first impurities.

### EXAMPLE 3

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus (P). A first source gas including TEB was supplied at a flow rate of about 280 sccm in order to dope silicon oxide with the first impurities. A second source gas including triethylphosphate (TEPO) was supplied at a flow rate of about 30 sccm into the silicon oxide.

### EXAMPLE 4

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus. A first source gas including TEB was supplied at a flow rate of about 240 sccm in order to dope the silicon oxide with the first impurities. A second source gas including TEPO was supplied at a flow rate of about 60 sccm into the silicon oxide.

### EXAMPLE 5

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus. A first source gas including TEB was supplied at a flow rate of about 200 sccm in order to dope the silicon oxide with the first impurities. A second source gas including TEPO was supplied at a flow rate of about 90 sccm into the silicon oxide.

### EXAMPLE 6

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus. A first source gas including TEB was supplied at a flow rate of about 160 sccm in order to dope the silicon oxide with the first impurities. A second source gas including TEPO was supplied at a flow rate of about 120 sccm into the silicon oxide.

### COMPARATIVE EXAMPLE 1

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus. A first source gas including TEB was supplied at a flow rate of about 120 sccm in order to dope the silicon oxide with the first impurities. A second source gas including TEPO was supplied at a flow rate of about 150 sccm into the silicon oxide.

### COMPARATIVE EXAMPLE 2

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus. A first source gas including TEB was supplied at a flow rate of about 80 sccm in order to dope the silicon oxide with the first impurities. A second source gas including TEPO was supplied at a flow rate of about 180 sccm into the silicon oxide.

### COMPARATIVE EXAMPLE 3

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with first impurities including boron and second impurities including phosphorus. A first source gas including TEB was supplied at a flow rate of about 40 sccm in order to dope the silicon oxide with the first impurities. A second source gas including TEPO was supplied at a flow rate of about 210 sccm into the silicon oxide.

### COMPARATIVE EXAMPLE 4

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with second impurities including phosphorus. A source gas including TEPO was supplied at a flow rate of about 240 sccm in order to dope the silicon oxide with the second impurities.

### COMPARATIVE EXAMPLE 5

An insulating interlayer was formed on a substrate to cover a lower structure formed on the substrate. An etch stop layer was formed on the insulating interlayer using silicon nitride. An insulation layer was formed on the etch stop layer by a CVD process using silicon oxide doped with second impurities including phosphorus. A source gas including TEPO was supplied at a flow rate of about 120 sccm in order to dope the silicon oxide with the second impurities.

Measurement of Flatness of Insulation Layers

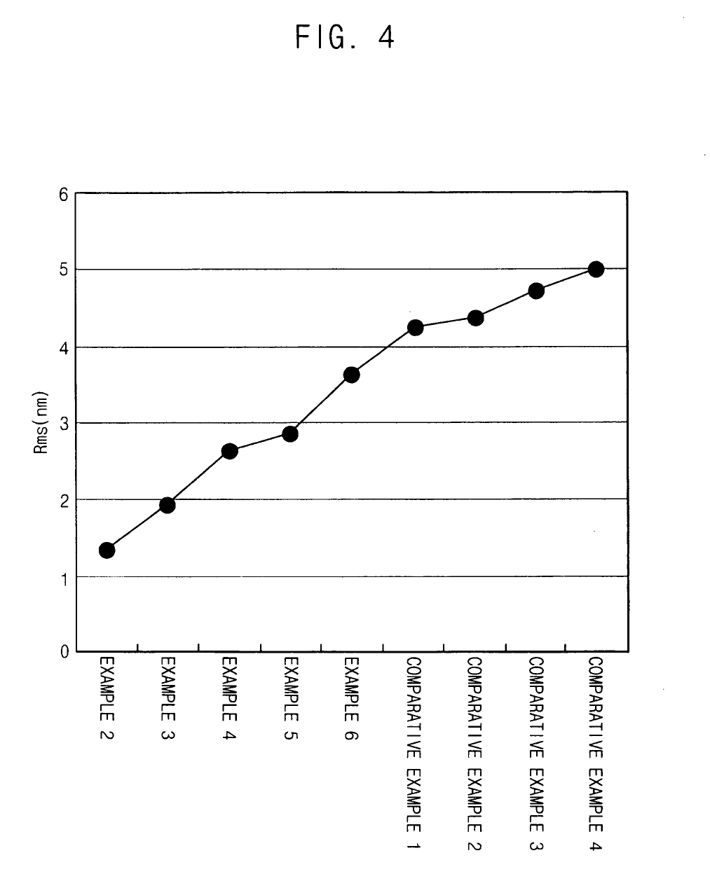

FIG. 4 is a graph illustrating a result of measuring a flatness of an insulation layer formed according to Examples 2 to 6 and Comparative Examples 1 to 4. Root mean square (RMS) values regarding the differences between peaks and valleys of the surfaces of the insulation layers were represented in FIG. 4 in order to measure the flatness of the insulation layers. Referring to FIG. 4, as a concentration of first impurities including boron that is doped into an insulation layer increases, a RMS value of the insulation layer may increase in inverse proportion to the concentration of the first impurities. In Example 2 excluding second impurities (e.g., phosphorus) and only including the first impurities (e.g., boron), the RMS value is about 1.3 nm. The insulation layer of Example 2 shows improved flatness.

As a concentration of second impurities including phosphorus that is doped into an insulation layer increases, a RMS value of the insulation layer may increase in proportion to the concentration of the second impurities. In Comparative Example 4 excluding first impurities (e.g., boron) and only including the second impurities (e.g., phosphorus), the RMS value is about 5.0 nm. The RMS value of Comparative Example 4 is about four times greater than that of Example 2. As a result, a flatness of the insulation layer may be improved in proportion to a concentration of the first impurities including an element in Group III and in inverse proportion to a concentration of the second impurities including an element in Group V. A flatness of an insulation layer may fluctuate according to the type and concentration of doped impurities. As the concentration of first impurities including the element in Group III increases, the flatness of the insulation layer may improve.

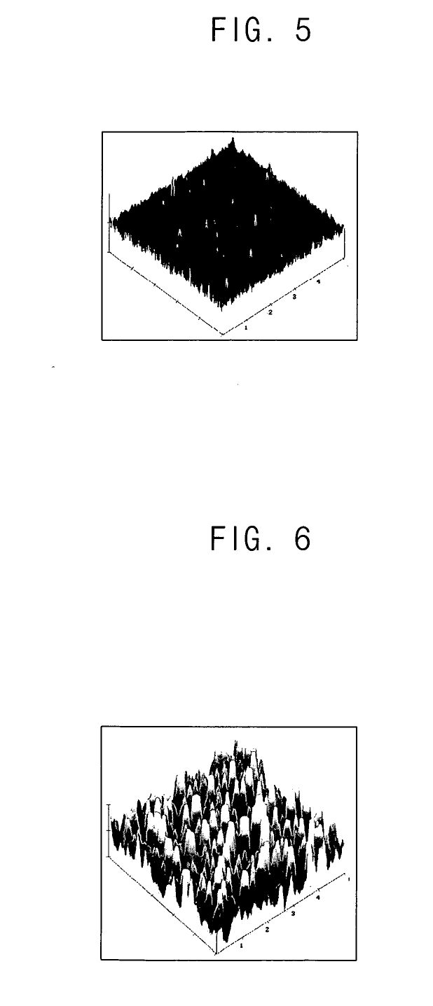

FIG. 5 is an atomic force microscopic picture illustrating a surface of an insulation layer according to Example 1. FIG. 6 is an atomic force microscopic picture illustrating a surface of an insulation layer in accordance with Comparative Example 5. Referring to FIG. 5, an insulation layer formed using only first impurities (e.g., boron (see Example 1)) may have a RMS value of about 0.374 nm and a RMAX value of about 6.811 nm. The insulation layer shown in Example 1 by using an AFM may display a flat surface. Referring to FIG. 6, an insulation layer formed using only second impurities (see Comparative Example 1) may have a RMS value of about 5.913 nm and a RMAX value of about 101.11 nm. Consequently, the insulation layer shown in Comparative Example 1 by using an AFM may display a rough surface.

In example embodiments, a flatness of an insulation layer may be controlled according to the type and concentration of doped impurities. When the insulation layer is formed by doping first impurities including an element in Group III, the insulation layer may have an improved flatness.

Method of Manufacturing a Capacitor

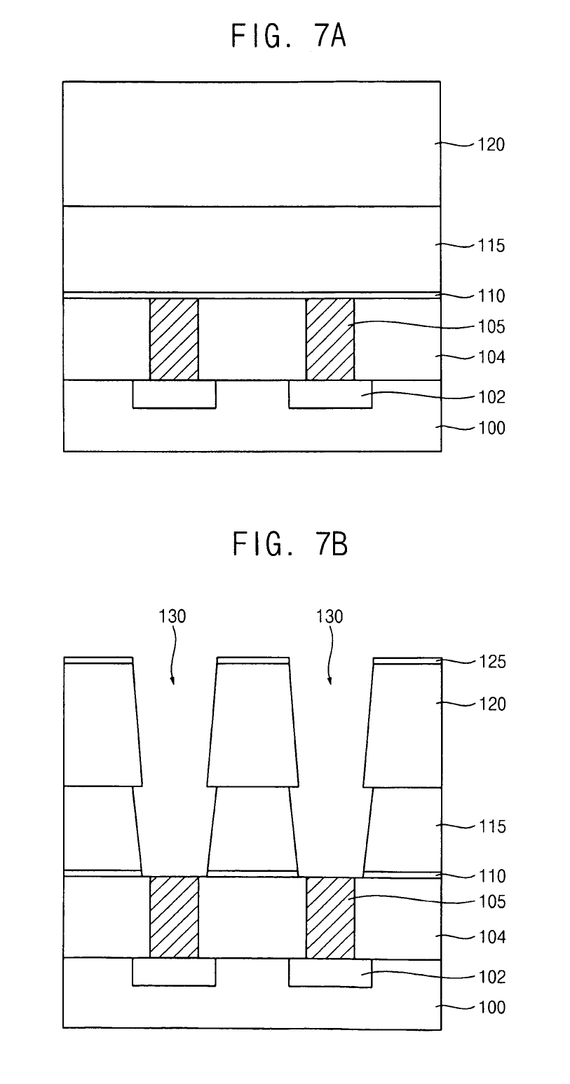

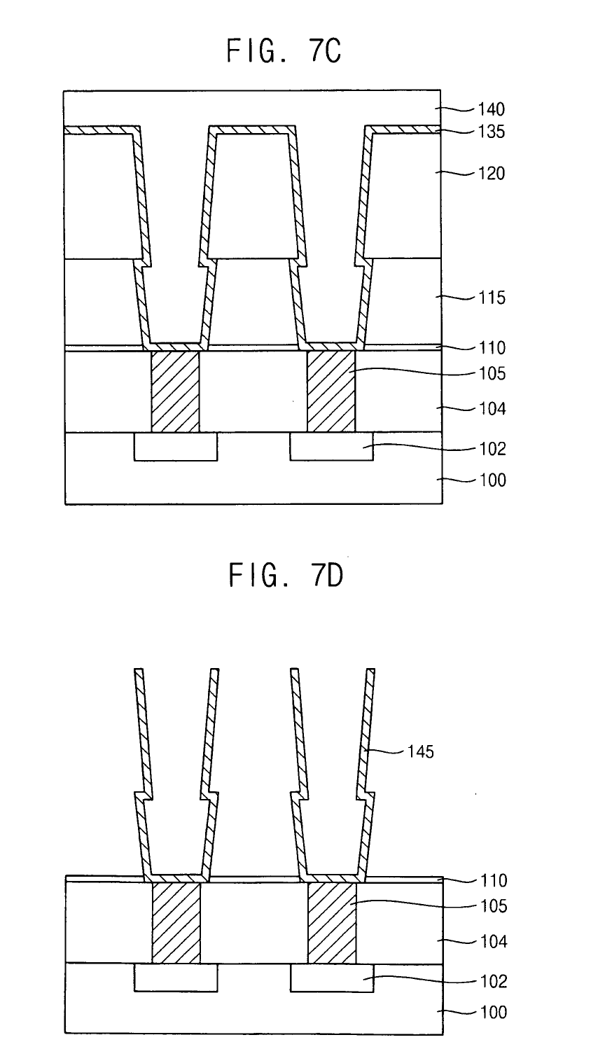

FIGS. 7A to 7D are diagrams illustrating a method of manufacturing a capacitor in accordance with example embodiments. Referring to FIG. 7A, a lower structure 102 may be formed on a substrate 100. The substrate 100 may include a silicon wafer and/or an SOI substrate. The lower structure 102 may include a contact region, a conductive wiring, a conductive pattern, a pad, a plug, a contact, a gate structure and/or a transistor.

At least one insulating interlayer 104 may be formed on the substrate 100 and the lower structure 102. The insulating interlayer 104 may be formed by a chemical vapor deposition (CVD) process, a plasma enhanced chemical vapor deposition (PECVD) process, a high density plasma-chemical vapor deposition (HPD-CVD) process and/or an atomic layer deposition (ALD) process. The insulating interlayer 104 may be formed using an oxide (e.g., silicon oxide).

In example embodiments, the insulating interlayer 104 may include silicon oxide doped with impurities. Flatness of the insulating interlayer 104 may fluctuate according to the type or concentration of doped impurities. For example, the flatness of the insulating interlayer 104 is improved in proportion to a concentration of first impurities including an element in Group III and in inverse proportion to a concentration of second impurities including an element in Group V.

In example embodiments, the insulating interlayer 104 may be formed by doping silicate glass with the first impurities including the element in Group III. The insulating interlayer 104 may be formed by doping silicate glass with the first impurities including the element in Group III and the second impurities including an element in Group V. For example, the first impurities may include boron (B) and the second impurities may include phosphorus (P) and/or arsenic (As). The insulating interlayer 104 may be partially removed by a CMP process, an etch back process and/or a combination process of CMP and etch back to planarize a surface of the insulating interlayer 104.

The insulating interlayer 104 may be selectively etched to form a contact hole exposing the lower structure 102. A conductive layer may be formed to fill the contact hole. The conductive layer is partially removed until the insulating interlayer 104 is exposed, thereby forming a pad 105 filling the contact hole. The pad 105 may be electrically connected to the lower structure 102 (e.g., another pad, a plug, a contact and/or a contact region). In example embodiments, the pad 105 may be electrically connected to the contact region formed on the substrate 100. An etch stop layer 110 may be formed on the insulating interlayer 104. The etch stop layer 110 may be formed using a material having an etching selectivity relative to the insulating interlayer 104. For example, when the insulating interlayer 104 is formed using an oxide (e.g., silicon oxide), the etch stop layer 110 may be formed using a nitride (e.g., silicon nitride).

A first insulation layer 115 may be formed on the etch stop layer 110. The first insulation layer 115 may be formed using an oxide (e.g., silicon oxide doped with impurities). The first insulation layer 115 may be formed using a material having an etching rate higher than that of a second insulation layer 120 to be formed in a subsequent process with respect to an etching material, which is used in a patterning process for forming a lower electrode. For example, when an etching solution including hydrogen fluoride (HF) is used for etching the first and the second insulation layers 115 and 120, the first insulation layer 115 may be formed using a material having an etching selectivity of about 2:1 to about 5:1 relative to that of the second insulation layer 120. The etching selectivity between the first insulation layer 115 and the second insulation layer 120 may fluctuate according to materials included in the first and the second insulation layers 115 and 120, respectively.

In example embodiments, the etching selectivity between the first insulation layer 115 and the second insulation layer 120 may fluctuate according to the type and concentration of the impurities doped into the first and the second insulation layers 115 and 120, respectively. For example, when the first insulation layer 115 is formed using silicon oxide with impurities, as the concentration of the impurities increases, an etching rate of the first insulation layer 115 with respect to an etching solution including hydrogen fluoride may increase. When the second insulation layer 120 is formed by doping impurities having a lower concentration than that of the first insulation layer 115, the second insulation layer 120 may have an etching rate lower than that of the first insulation layer 115. A flatness of the first insulation layer 115 may vary according to the type and the concentration of impurities doped therein.

In example embodiments, the first insulation layer 115 may be formed by doping silicate glass with first impurities including an element in Group III (e.g., boron (B)). The first insulation layer 115 may be formed by doping silicate glass with the first impurities including the element in Group III (e.g., boron) and second impurities including an element in Group V (e.g., phosphorus (P) and/or arsenic (As)). The flatness of the first insulation layer 115 may improve in proportion to the concentration of the first impurities and in inverse proportion to the concentration of the second impurities. As the concentration of the first impurities increase, the flatness of the first insulation layer 115 may improve. As the concentration of the second impurities decreases, the flatness of the first insulation layer 115 may improve.

When the first insulation layer 115 is formed by a CVD process, a first source gas including an ozone (O₃) gas and a silane (SiH₄) gas may be applied to form a silicon oxide layer, and a second source gas including triethylborate (TEB) may be applied to dope the silicon oxide layer with the first impurities. The second source gas including TEB and a third source gas including triethylphosphate (TEPO) may be applied to dope the silicon oxide layer with the first and the second impurities. A flow rate ratio between the second sources gas and the third source gas may be in a range of about 1.0:0.1 to about 1.0:5.5, for example, in a range of about 1.0:0.1 to about 1.0:1.0. When the second source gas is supplied with a flow rate greater than that of the third source gas, the flatness of the first insulation layer 115 may improve.

The flatness of the first insulation layer 115 may influence the flatness of an upper structure including the second insulation layer 120, a mask pattern 125 (see FIG. 7B) and a photoresist pattern formed on the first insulation layer 115 in a subsequent process. Accordingly, when the flatness of the first insulation layer 115 is fluctuated by adjusting the type and the concentration of the impurities, the flatness of the upper structure may be determined according to the flatness of the first insulation layer 115. When the first insulation layer 115 has a flat surface, the upper structure may also have a flat surface. An additional process (e.g., a CMP process and/or a re-flow process) may not be required after forming the first insulation layer 115.

A thickness of the first insulation layer 115 may be determined according to a capacitance required to a capacitor. Because a height of the capacitor is mainly decided according to the thicknesses of the first and the second insulation layers 115 and 120, the thickness of the first insulation layer 115 may be determined according to the capacitor required to a semiconductor device. The second insulation layer 120 may be formed on the first insulation layer 110. In example embodiments, the second insulation layer 120 may be formed using tetraethyl orthosilicate (TEOS), plasma enhanced-tetraethyl orthosilicate (PE-TEOS), high density plasma-chemical vapor deposition (HDP-CVD) oxide, undoped silicate glass (USG) and/or spin on glass (SOG). The second insulation layer 120 may be formed using a material having a lower etching rate than the first insulation layer 115.

For example, when an etching solution including hydrogen fluoride is used for etching the second insulation layer 120, the second insulation layer 120 may be formed using a material having an etching selectivity of about 1:2 to about 1:5 relative to the first insulation layer 115. In example embodiments, when the first insulation layer 115 is formed using an oxide doped with the first and/or the second impurities, the second insulation layer 120 may be formed using an oxide that is not doped with impurities, (e.g., USG, TEOS and/or PE-TEOS). For example, the second insulation layer 120 may be formed using TEOS. When the second insulation layer 120 is formed using TEOS, the second insulation layer 120 may have a lower etching rate than that of the first insulation layer 115 with respect to an etching solution including hydrogen fluoride.

Referring to FIG. 7B, a mask layer may be formed on the second insulation layer 120. The mask layer may be formed using a material having an etching selectivity relative to that of the second insulation layer 120. For example, when the second insulation layer 120 may include an oxide (e.g., silicon oxide), the mask layer may be formed using a nitride (e.g., silicon nitride). A photoresist pattern (not shown) may be formed on the mask layer. The mask layer may be patterned using the photoresist pattern as an etching mask to form a mask pattern 125 on the second insulation layer 120. The photoresist pattern may be removed by an ashing process and/or a stripping process. The second and the first insulation layers 120 and 115, and the etch stop layer 110 may be successively etched using the mask pattern 125 as an etching mask. A hole 130 exposing the pad 105 may be formed through the second and the first insulation layers 120 and 115 and the etch stop layer 110.

In example embodiments, the hole 130 may be formed by a wet etching process using an etching solution including a standard cleaning-1 (SC-1) solution and/or a hydrogen fluoride solution. The first insulation layer 115 may have an etching selectivity relative to the second insulation layer 120, so that the first insulation layer 115 may be more intensively etched while the second insulation layer 120 is etched. A critical dimension of a lower portion of the hole 130 may be expanded, so the pad 105 may be sufficiently exposed by the hole 130. Because the hole 130 is not straightened but folded at a boundary line between the first insulation layer 115 and the second insulation layer 120 (see FIG. 7B), an area of the sidewall of the hole 130 may be enlarged. Accordingly, the capacitance of the capacitor may increase.

In example embodiments, an anti-reflective layer may be further formed on the mask layer. A photoresist pattern may be directly formed on the second insulation layer 115. An etching process using the photoresist pattern as an etching mask may be performed to form the hole 130 exposing the pad 105. After forming the hole 130, a cleaning process may be further performed in the hole 130. The cleaning process may remove contaminants (e.g., particles that remain in the hole 130). The cleaning process may include a wet etching process using an etching solution (e.g., an SC-1 solution and/or a hydrogen fluoride solution).

Referring to FIG. 7C, the mask pattern 125 may be removed from the second insulation layer 120. A conductive layer 135 for forming a lower electrode may be formed on the pad 105 exposed by the hole 130, on a sidewall of the hole 130 and on the second insulation layer 120. The conductive layer 135 may be formed using polysilicon, which is highly doped with N type impurities and/or P type impurities, a metal and/or a conductive metal nitride. The conductive layer 135 may be formed by a low pressure chemical vapor deposition (LPCVD) process and a doping process in order to have a uniform thickness.

A sacrificial layer 140 may be formed on the conductive layer 135 to fill the hole 130. The sacrificial layer 140 may be formed using an oxide, for example, HDP-CVD oxide, PE-TEOS, USG, BPSG, PSG and/or SOG. In example embodiments, the sacrificial layer 140 may be formed using a material substantially the same as that of the second insulation layer 120. The sacrificial layer 140 may be formed using a material different from that of the second insulation layer 120. The sacrificial layer 140 may serve to protect the conductive layer 135 in forming a lower electrode. In example embodiments, the mask pattern 125 may not be removed to serve as an etch stop layer in an etching process.

Referring to FIG. 7D, the sacrificial layer 140 and the conductive layer 135 on the second insulation layer 120 may be removed until the second insulation layer 120 is exposed. The sacrificial layer 140 that remains in the hole 130, the second insulation layer 120 and the first insulation layer 115 may be successively removed by a stripping process. The conductive layer 135 may be separated into a unit cell to form a lower electrode 145. The stripping process may be performed using, for example, a solution including hydrogen fluoride. After forming the lower electrode 145, a dielectric layer and an upper electrode may be formed on the lower electrode 145 to form a capacitor including the lower electrode 145, the dielectric layer and the upper electrode.

Evaluation of Characteristics of a Capacitor

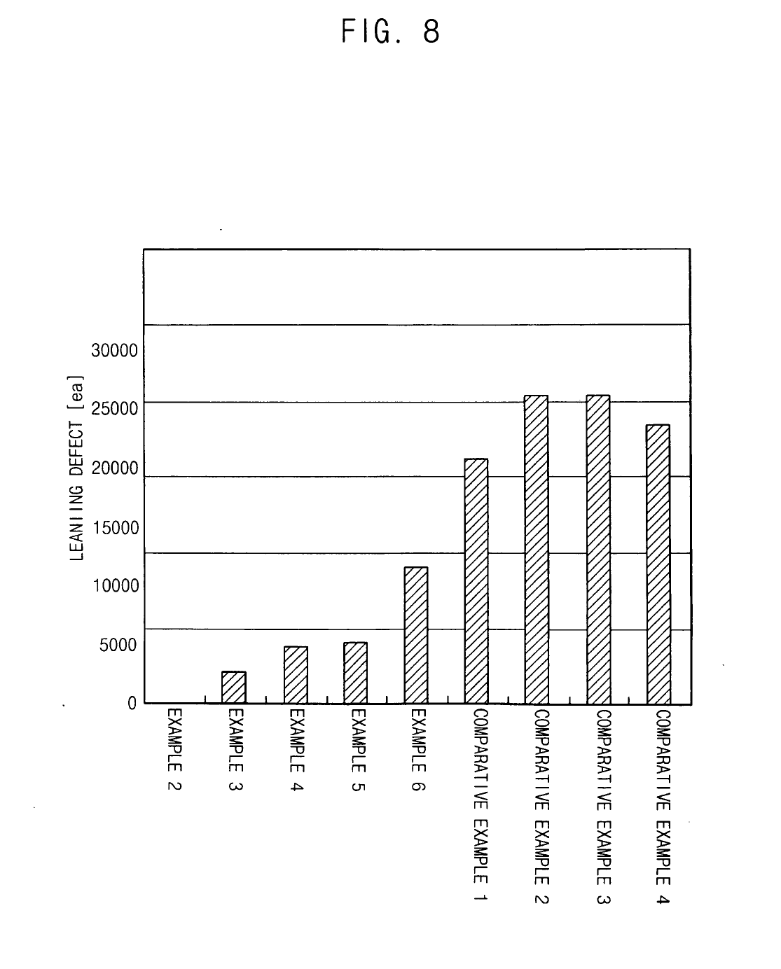

Characteristics of an insulation layer of example embodiments will be further described with reference to various Examples and Comparative Examples. FIG. 8 is a graph illustrating a result of measuring numbers of leaning defects of a capacitor including a first insulation layer 115 formed according to Examples 2 to 6 and Comparative Examples 1 to 4. The leaning defects may occur because a distance between lower electrodes of adjacent capacitors is close. The leaning defects may cause a 2-bit failure. The leaning defects may increase as a flatness of a first insulation layer 115 is deteriorated so that numbers of the leaning defects may reflect the flatness of the first insulation layer 115.

Referring to FIG. 8, as a concentration of first impurities including boron that is doped into a first insulation layer 115 increases, leaning defects of a capacitor may be generated in inverse proportion to the concentration of the first impurities. In Example 2 excluding second impurities (e.g., phosphorus) and only including the first impurities (e.g., boron), the leaning defects may not occur at all. As the concentration of second impurities including phosphorus that is doped into a first insulation layer 115 increases, leaning defects of a capacitor may be generated in proportion to the concentration of the second impurities. In Comparative Examples 2 and 3, more than about 25,000 leaning defects may be generated per each wafer.

As a result, leaning defects caused by deteriorating the flatness of a first insulation layer 115 may be generated in proportion to a concentration of the first impurities including an element in Group III and in inverse proportion to a concentration of the second impurities including an element in Group V. A flatness of a first insulation layer 115 may improve by adjusting the type and concentration of doped impurities so that leaning defects of a capacitor using the first insulation layer 115 may decrease.

Method of Manufacturing a Semiconductor Device

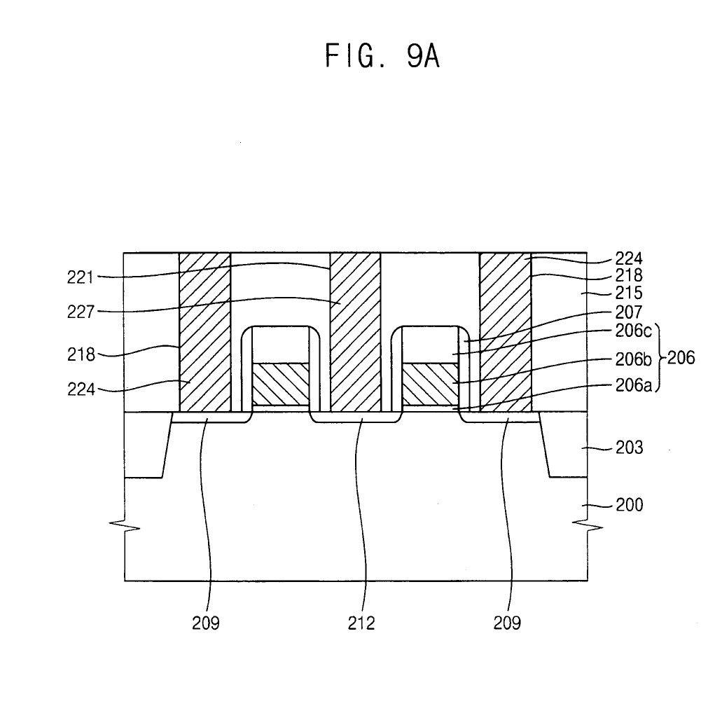

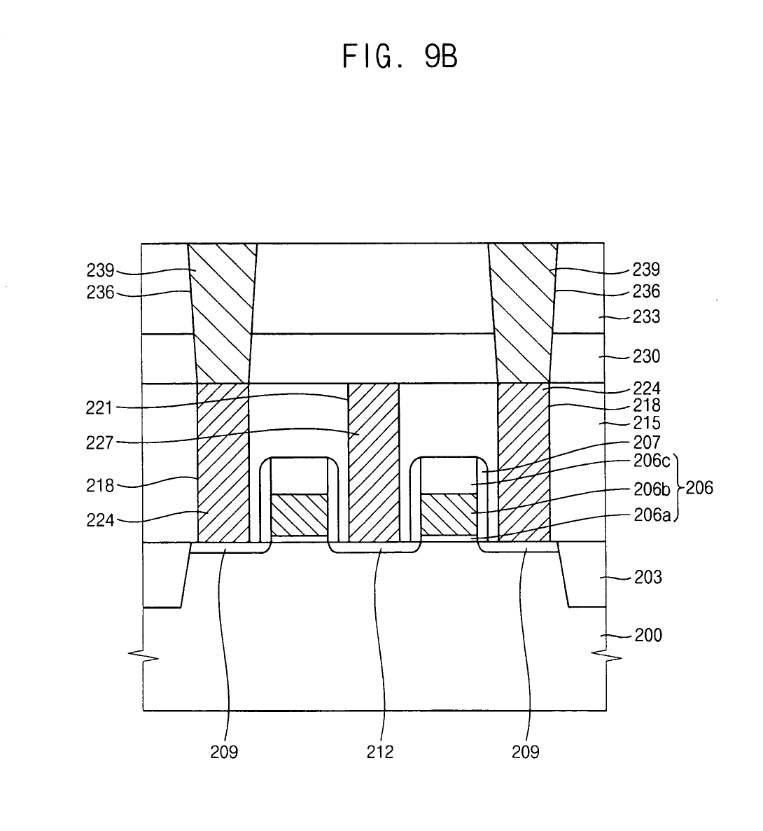

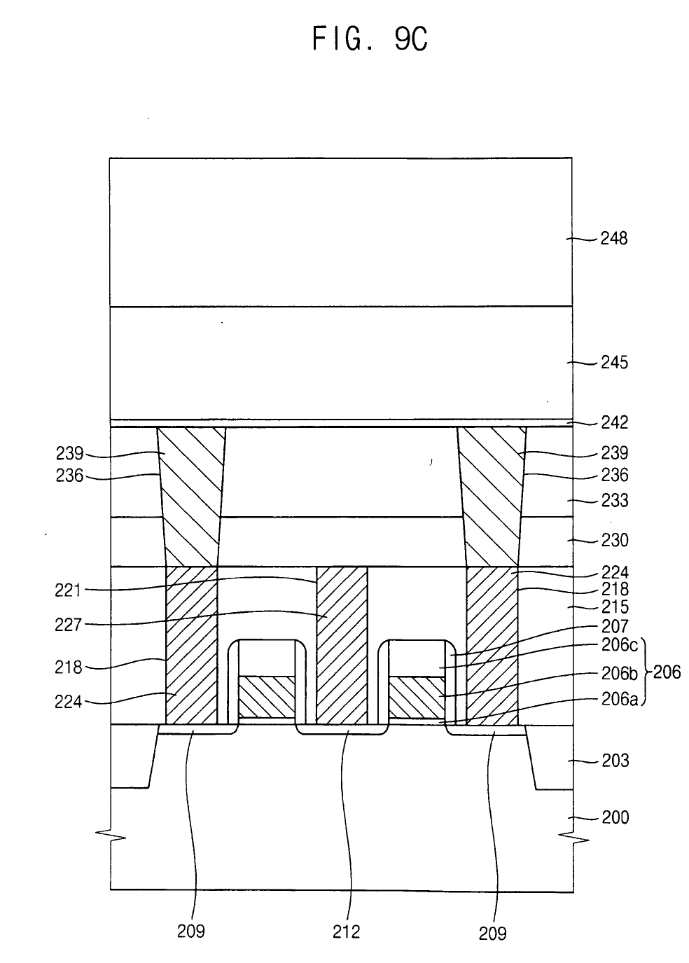

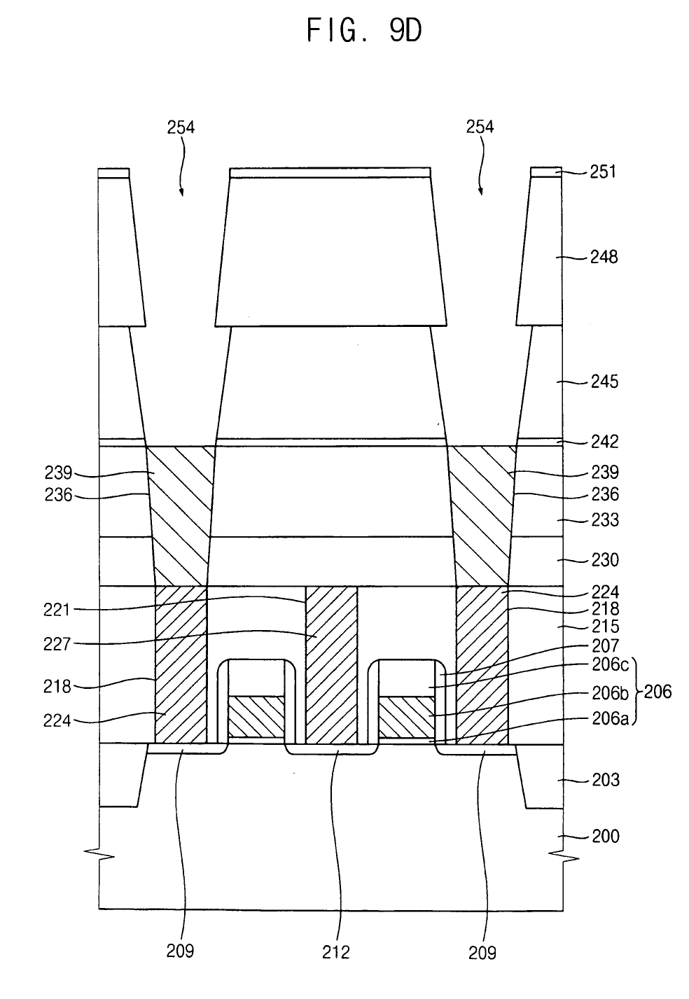

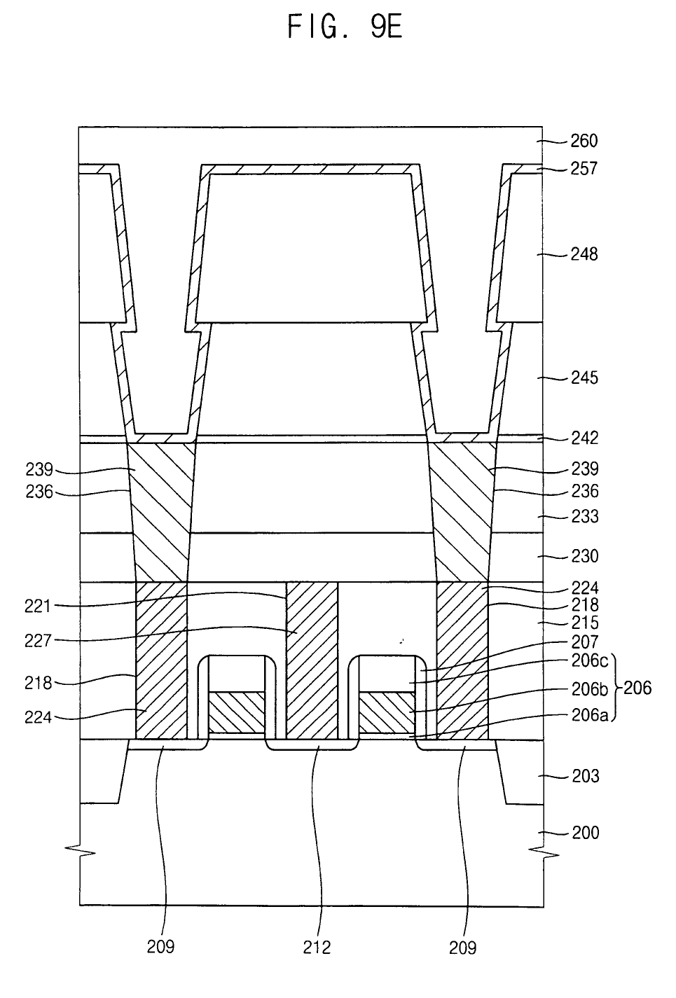

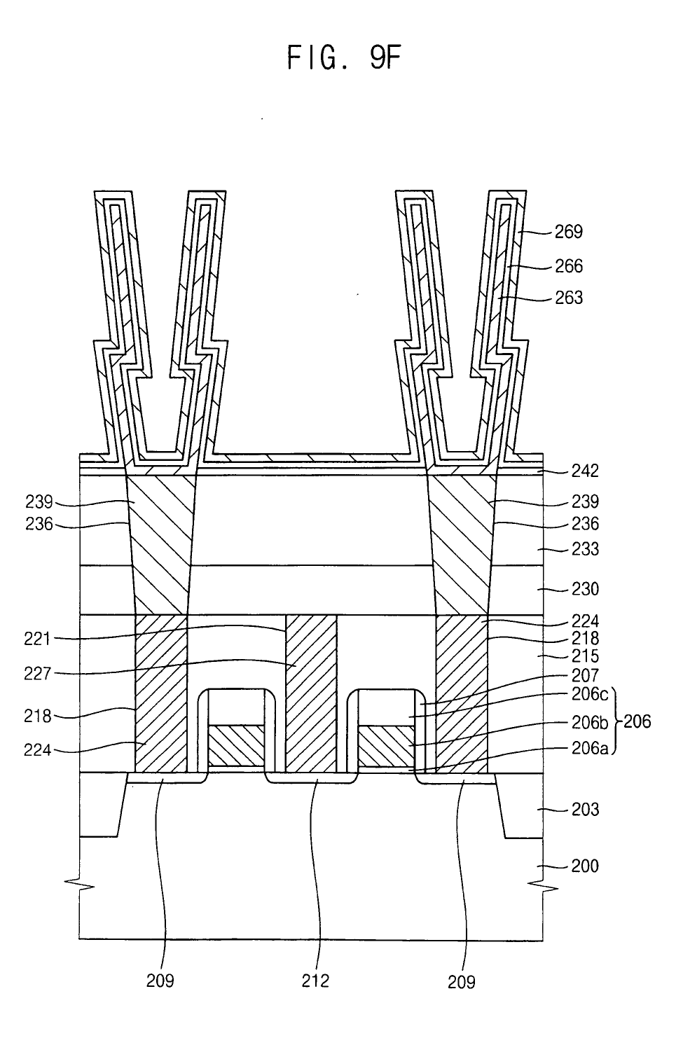

FIGS. 9A to 9F are diagrams illustrating a method of manufacturing a semiconductor device in accordance with example embodiments. Referring to FIG. 9A, an isolation layer 203 may be formed on a substrate 200 by an isolation process (e.g., a shallow trench isolation (STI) process and/or a local oxidation of silicon (LOCOS) process). An active region and a field region may be defined in the substrate 200 by the isolation layer 203. The substrate 200 may include a silicon substrate, a silicon germanium substrate and/or an SOI substrate.

A gate oxidation layer may be formed on the substrate 200 including the isolation layer 203 therein. The gate oxidation layer may be formed by a thermal oxidation process and/or a CVD process. The gate oxidation layer may be formed on the active region of the substrate 200 defined by the isolation layer 203. The gate oxidation layer may be patterned to a gate oxidation layer pattern 206a.

A gate conductive layer and a gate mask layer may be successively formed on the gate oxidation layer. The gate conductive layer may be formed using polysilicon doped with impurities and patterned to a gate conductive layer pattern 206b. The gate conductive layer may be formed in a polycide structure including a polysilicon layer and a metal silicide layer. The gate mask layer may be patterned to a gate mask pattern 206c. The gate mask layer may be formed using a material having an etching selectivity relative to that of a first insulating interlayer 215 formed in a subsequent process. For example, when the first insulating interlayer 215 is formed using an oxide, the gate mask layer may be formed using a nitride (e.g., silicon nitride). The gate mask layer, the gate conductive layer and the gate oxidation layer may be successively patterned by a photolithography process to form a gate structure 206 on the substrate 200. The gate structure 206 may include the gate oxidation layer pattern 206a, the gate conductive layer pattern 206b and the gate mask pattern 206c.

An insulation layer may be formed using a nitride (e.g., silicon nitride) on the substrate 200 including the gate structure 206 thereon. The insulation layer may be anisotropically etched to form a gate spacer 207 on a sidewall of the gate structure 206. A plurality of word lines including the gate structure 206 and the gate spacer 207 may be formed on the substrate 200 parallel to each other. Ions may be implanted in the substrate 200 exposed between the word lines by an ion implantation process. The word lines may be used as an ion implantation mask. A thermal treatment process may be further performed to form a first contact region 209 and a second contact region 212 on the substrate 200. For example, the first contact region 209 may correspond to a source region and the second contact region 212 may correspond to a drain region. Transistor structures including the first and the second contact regions 209 and 212, and the word lines may be formed on the substrate 200.

In example embodiments, first ions having a low concentration may be implanted into the substrate 200 exposed between the gate structures 206 before forming the gate spacer 207. After forming the gate spacer 207 on the sidewall of the gate structure 206, second ions having a high concentration may be implanted into the substrate 200 to form the first and the second contact regions 209 and 212. The first and the second contact regions 209 and 212 may have a lightly doped drain (LDD) structure. The first insulating interlayer 215 may be formed on the substrate 200 using an oxide to cover the transistor structures. The first insulating interlayer 215 may be formed by a CVD process, a PECVD process, an ALD process and/or an HDP-CVD process. The first insulating interlayer 215 may be formed using an oxide (e.g., silicon oxide doped with impurities).

In example embodiments, a flatness of the first insulation layer 215 may be varied in accordance with the type and concentration of doped impurities. The first insulating interlayer 215 may be formed by doping silicate glass with first impurities including an element in Group Ill. For example, the first impurities may include boron (B). The first insulating interlayer 215 may be formed by doping silicate glass with the first impurities including a Group III element and second impurities including an element in Group V. For example, the first impurities may include boron and the second impurities may include phosphorus (P) and/or arsenic (As). A flatness of the first insulating interlayer 215 may improve in proportion to the concentration of the first impurities including the element in Group III and in inverse proportion to the concentration of the second impurities including the element in Group V. The flatness of the first insulating interlayer 215 may improve by adjusting the concentration of the first and the second impurities.

In example embodiments, the first insulating interlayer 215 may be partially removed by a CMP process, an etch back process and/or a combination process of CMP and etch back to planarize the first insulating interlayer 215. The first insulating interlayer 215 may have a predetermined or given height from the gate structure 206. The first insulating interlayer 215 may be removed until an upper surface of the gate structure 206 is exposed. A first photoresist pattern (not shown) may be formed on the first insulating interlayer 215. The first insulating interlayer 215 may be etched using the first photoresist pattern as an etching mask to form a first hole 218 and a second hole 221. The first and the second holes 218 and 221 may expose the first and the second contact regions 209 and 212, respectively.

The first photoresist pattern may be removed by an ashing process and/or a stripping process. A first conductive layer may be formed on the first insulating interlayer 215 to fill the first and the second holes 218 and 221. The first conductive layer may be formed using doped polysilicon or a metal. The first conductive layer may be partially removed by a CMP process, an etch back process and/or a combination process of CMP and etch back until the first insulating interlayer 215 is exposed.

A first pad 224 may be formed in the first hole 218 and a second pad 227 may be simultaneously formed in the second hole 221. The first pad 224 may be electrically connected to the first contact region 209 and the second pad 227 may be electrically connected to the second contact region 212. For example, the first pad 224 may correspond to a capacitor contact pad and the second pad 227 may correspond to a bit line contact pad. In example embodiments, when the first insulating interlayer 215 may have a height substantially the same as that of the gate structure 206, the first conductive layer may be removed until the gate structure 206 is exposed. The first and the second pads 224 and 227 may be formed as self-aligned contact pads.

Referring to FIG. 9B, a second insulating interlayer 230 may be formed on the first insulating interlayer 215 including the first and the second pads 224 and 227 therein. The second insulating interlayer 230 may serve to electrically insulate the first pad 224 with a bit line formed in a subsequent process. The second insulating interlayer 230 may be formed using an oxide (e.g., silicon oxide). The second insulating interlayer 230 may be formed using an oxide substantially the same as that of the first insulating interlayer 215. The second insulating interlayer 230 may be formed using an oxide different from that of the first insulating interlayer 215.

In example embodiments, a flatness of the second insulation layer 230 may fluctuate according to the type and concentration of doped impurities. The flatness of the second insulating interlayer 230 may improve in proportion to the concentration of first impurities including an element in Group III and in inverse proportion to the concentration of second impurities including an element in Group V. As the concentration of the first impurities increases, the flatness of the second insulation layer 230 may improve. As the concentration of the second impurities increases, the flatness of the second insulation layer 230 may deteriorate. The flatness of the second insulating interlayer 230 may improve by adjusting the concentration of the first and the second impurities.

In example embodiments, the second insulating interlayer 230 may be partially removed by a CMP process, an etch back process and/or a combination process of CMP and etch back to planarize the second insulating interlayer 230. A bit line (not shown) may be formed in the first insulating interlayer 230. The bit line may include a bit line conductive layer pattern and a bit line mask pattern. A third insulating interlayer 233 may be formed on the second insulating interlayer 230 to cover the bit line. The third insulating interlayer 233 may be formed using an oxide (e.g., silicon oxide). The third insulating interlayer 233 may be formed using an oxide substantially the same as that of the second insulating interlayer 230 or different from that of the second insulating interlayer 230.

In example embodiments, a flatness of the third insulation layer 233 may fluctuate according to the type and concentration of doped impurities. More precisely, the flatness of the third insulating interlayer 233 may improve in proportion to the concentration of first impurities including a Group III element and in inverse proportion to the concentration of second impurities including a Group V element. As a concentration of the first impurities increases, the flatness of the third insulation layer 233 may improve. As a concentration of the second impurities increases, the flatness of the third insulation layer 233 may deteriorate. The flatness of the third insulation layer 233 may improve by adjusting the concentration of the first and the second impurities.

In example embodiments, the third insulating interlayer 233 may be partially removed by a CMP process, an etch back process and/or a combination process of CMP and etch back to planarize the third insulating interlayer 233. A second photoresist pattern (not shown) may be formed on the third insulating interlayer 233. The third insulating interlayer 233 may be etched using the second photoresist pattern as an etching mask to form a third hole 236. The third hole 236 may expose the first pad 224 through the second and the third insulating interlayers 230 and 233.

A second conductive layer may be formed on the third insulating interlayer 233 to fill the third hole 236. The second conductive layer may be partially removed until the third insulating interlayer 233 is exposed. A third pad 239 may be formed in the third hole 236. The third pad 239 may include polysilicon doped with impurities, a metal and/or a conductive metal nitride. The third pad 239 may electrically connect the first pad 224 with a lower electrode 263 (see FIG. 9F).

Referring to FIG. 9C, an etch stop layer 242 may be formed on the third pad 239 and the third insulating interlayer 233. The etch stop layer 242 may be formed using a material having an etching selectivity relative to that of the third insulating interlayer 233. For example, the etch stop layer 242 may be formed using a nitride (e.g., silicon nitride).

A first insulation layer 245 may be formed on the etch stop layer 242. The first insulation layer 245 may be formed using an oxide (e.g., silicon oxide doped with impurities). The first insulation layer 245 may be formed using a material having a higher etching rate than a second insulation layer 248 to be formed in a subsequent process with respect to an etching material used in a patterning process for a lower electrode. For example, when an etching solution including hydrogen fluoride (HF) is used for etching the first insulation layer 245, the first insulation layer 245 may be formed using a material having an etching selectivity of about 2:1 to about 5:1 relative to the second insulation layer 248.

The etching selectivity between the first insulation layer 245 and the second insulation layer 248 may fluctuate according to materials consisting of the first and the second insulation layers 245 and 248, respectively. In example embodiments, the etching selectivity between the first insulation layer 245 and the second insulation layer 248 may fluctuate according to the type and concentration of the impurities to be doped to the first and the second insulation layers 245 and 248. For example, when the first and the second insulation layers 245 and 248 are formed using silicon oxide with impurities, etching rates of the first and the second insulation layers 245 and 248 with respect to an etching solution including hydrogen fluoride may increase as the concentration of the impurities increases. A flatness of the first insulation layer 245 may fluctuate according to the type and concentration of doped impurities.

In example embodiments, the first insulation layer 245 may be formed by doping silicate glass with first impurities including an element in Group III (e.g., boron (B)). The first insulation layer 245 may be formed by doping silicate glass with the first impurities including the element in Group III (e.g., boron (B)) and second impurities including an element in Group V (e.g., phosphorus (P) and/or arsenic (As)).

The flatness of the first insulation layer 245 may improve in proportion to the concentration of the first impurities and in inverse proportion to the concentration of the second impurities. The flatness of the first insulation layer 245 may influence the flatness of an upper structure including the second insulation layer 245 to be formed in a subsequent process. Accordingly, the flatness of the upper structure including the second insulation layer 248 may be controlled according to the flatness of the first insulation layer 245.

When the first insulation layer 245 is formed by a CVD process, a first source gas including an ozone (O₃) gas and a silane (SiH₄) gas may be applied to form a silicon oxide layer, and a second source including triethylborate (TEB) may be applied to dope the silicon oxide with the first impurities layer. The second source gas including TEB and a third source gas including triethylphosphate (TEPO) may be applied to dope the silicon oxide layer with the first and the second impurities. A flow rate ratio between the second sources gas and the third source gas may be in a range of about 1.0:0.1 to about 1.0:5.5, for example, in a range of about 1.0:0.1 to about 1.0:1.0. When the second source gas is supplied at the flow rate greater than that of the third source gas, the flatness of the first insulation layer 245 may improve.

Accordingly, when the flatness of the first insulation layer 245 is determined by adjusting the type and the concentration of the impurities, an additional process (e.g., a CMP process and/or a re-flow process) may not be required for improving the flatness of the first insulation layer 245. Frequency of leaning defects, which may occur due to a deteriorated flatness of the first insulation layer 245, may decrease. A thickness of the first insulation layer 245 may be determined according to a capacitor required to a semiconductor device.

The second insulation layer 248 may be formed on the first insulation layer 245. The second insulation layer 248 may be formed using TEOS, PE-TEOS, HDP-CVD oxide, USG and/or SOG. The second insulation layer 248 may be formed using a material having a lower etching rate than the first insulation layer 245. For example, when an etching solution including hydrogen fluoride is used for etching the second insulation layer 248, the second insulation layer 248 may be formed using a material having an etching selectivity of about 1:2 to about 1:5 relative to the first insulation layer 245. The etching selectivity may fluctuate according to a concentration of impurities to be doped into the first and the second insulation layers 245 and 248. When the first insulation layer 245 is formed using an oxide doped with the first and/or the second impurities, the second insulation layer 248 may be formed using an oxide that is not doped with impurities (e.g. USG, TEOS and/or PE-TEOS). For example, the second insulation layer 120 may be formed using TEOS. When the second insulation layer 248 is formed using TEOS, the second insulation layer 248 may have a lower etching rate than that of the first insulation layer 245 with respect to an etching solution including hydrogen fluoride.

Referring to FIG. 9D, a mask layer may be formed on the second insulation layer 248. The mask layer may be formed using a material having an etching selectivity relative to that of the second insulation layer 248. A third photoresist pattern (not shown) may be formed on the mask layer. The mask layer may be patterned using the third photoresist pattern as an etching mask to form a mask pattern 251 on the second insulation layer 248. The third photoresist pattern may be removed by an ashing process and/or a stripping process. The second and the first insulation layers 248 and 245 and the etch stop layer 242 may be successively etched using the mask pattern 251 as an etching mask. A third hole 254 exposing the third pad 239 may be formed through the second and the first insulation layers 248 and 245 and the etch stop layer 242.

The third hole 254 may be formed by a wet etching process using an etching solution including an SC-1 solution and/or a hydrogen fluoride solution. The first insulation layer 245 may have an etching selectivity relative to the second insulation layer 248, so that the first insulation layer 245 may be etched more intensively while the second insulation layer 248 is etched. A critical dimension of a lower portion of the hole 254 may be expanded hence the third pad 239 may be sufficiently exposed by the hole 254. Because a sidewall of the hole 254 is not straightened but folded at a boundary line between the first insulation layer 245 and the second insulation layer 248, an area of the sidewall of the hole 254 may be enlarged. Accordingly, the capacitance of the capacitor may increase.

In example embodiments, an anti-reflective layer may be further formed on the mask layer. A third photoresist pattern may be directly formed on the second insulation layer 248. An etching process using the third photoresist pattern as an etching mask may be performed to form the hole 254 exposing the third pad 239. After forming the hole 254, a cleaning process may be further performed on the hole 254. The cleaning process may remove contaminants (e.g., particles that remain in the hole 254). The cleaning process may include a wet etching process using an etching solution (e.g., an SC-1 solution and/or a hydrogen fluoride solution).

Referring to FIG. 9E, the mask pattern 251 may be removed from the second insulation layer 248. A third conductive layer 257 for forming a lower electrode may be formed on the third pad 239 exposed by the hole 254, on a sidewall of the hole 254 and on the second insulation layer 248. The third conductive layer 257 may be formed using polysilicon highly doped with N type impurities and/or P type impurities, a metal and/or a conductive metal nitride. The third conductive layer 257 may be formed by an LPCVD process and a doping process in order to have a uniform thickness.

A sacrificial layer 260 may be formed on the third conductive layer 257 to fill the hole 254. The sacrificial layer 260 may be formed using an oxide (e.g., HDP-CVD oxide, PE-TEOS, USG, BPSG, PSG and/or SOG). The sacrificial layer 260 may be formed using a material substantially the same as that of the second insulation layer 248. The sacrificial layer 260 may be formed using a material different from that of the second insulation layer 248. The sacrificial layer 260 may serve to protect the third conductive layer 257 in a formation of a lower electrode. In example embodiments, the mask pattern 251 may not be removed, thereby serving as an etch stop layer in an etching process.

Referring to FIG. 9F, the sacrificial layer 260 and the third conductive layer 257 on the second insulation layer 248 may be removed until the second insulation layer 248 is exposed. The sacrificial layer 260 that remains in the hole 254, the second insulation layer 248 and the first insulation layer 245 may be successively removed by a stripping process. The third conductive layer 257 may be divided into a unit cell to form a lower electrode 263. For example, the stripping process may be performed using a solution including hydrogen fluoride. After forming the lower electrode 263, a dielectric layer 266 may be formed. An upper electrode 269 may be formed on the dielectric layer 266 to form a capacitor including the lower electrode 263, the dielectric layer 266 and the upper electrode 269.

According to example embodiments, a flatness of an insulation layer may fluctuate according to the type and concentration of doped impurities. The insulation layer may be formed by doping silicate glass with first impurities including an element in Group III (e.g., boron (B)). The first insulation layer may be also formed by doping silicate glass with the first impurities including the element in Group III (e.g., boron (B)) and second impurities including an element in Group V (e.g., phosphorus (P) and/or arsenic (As)). The flatness of the insulation layer may improve in proportion to the concentration of the first impurities and in inverse proportion to the concentration of the second impurities. Accordingly, the flatness of the insulation layer may be determined by adjusting the type and the concentration of the impurities, so that an additional process (e.g., a CMP process and/or a re-flow process) may not be required after forming the insulation layer.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A layer structure comprising:
a first insulation layer on a structure, wherein the first insulation layer includes at least one kind of impurities and a flatness of the first insulation layer varies in accordance with a type and a concentration of the impurities.

2. The layer structure of claim 1, wherein the first insulation layer includes an oxide doped with first impurities including an element in Group III.

3. The layer structure of claim 2, wherein the flatness of the first insulation layer is improved in proportion to a concentration of the first impurities.

4. The layer structure of claim 2, wherein the first impurities include boron (B).

5. The layer structure of claim 2, wherein the first insulation layer further includes:
second impurities including an element in Group V.

6. The layer structure of claim 5, wherein the flatness of the first insulation layer is improved in inverse proportion to a concentration of the second impurities.

7. The layer structure of claim 5, wherein the second impurities include phosphorus (P) or arsenic (As).

8. The layer structure of claim 1, wherein the structure includes a conductive structure and/or an insulation structure formed on a substrate.

9. A method of forming a layer structure comprising:
forming a structure on a substrate; and
forming a first insulation layer on the structure, wherein the first insulation layer includes at least one kind of impurities and a flatness of the first insulation layer varies in accordance with a type and a concentration of the impurities.

10. The method of claim 9, wherein forming the first insulation layer on the structure includes:
forming an oxide layer on the structure; and
doping first impurities including an element in Group III into the oxide layer.

11. The method of claim 10, wherein forming the oxide layer and doping the first impurities are simultaneously performed.

12. The method of claim 10, wherein forming the oxide layer includes supplying a first source gas including an ozone (O₃) gas and a silane (SiH₄) gas onto the structure, and the first impurities are doped by supplying a second source gas including triethylborate (TEB) onto the oxide layer.

13. The method of claim 9, wherein forming the first insulation layer on the structure includes:
forming the oxide layer on the structure;
doping first impurities including an element in Group III into the oxide layer; and
doping second impurities including an element in Group V into the oxide layer.

14. The method of claim 13, wherein doping the first impurities and doping the second impurities are simultaneously performed.

15. The method of claim 13, wherein forming the oxide layer includes supplying a first source gas including an ozone gas and a silane gas onto the structure, the first impurities are doped by supplying a second source gas including triethylborate (TEB) onto the oxide layer, and the second impurities are doped by supplying a third source gas including triethylphosphate (TEPO) onto the oxide layer.

16. The method of claim 15, wherein a flow rate ratio between the second source gas and the third source gas is in a range of about 1.0:0.1 to about 1.0:5.5.

17. The method of claim 16, wherein a flow rate ratio between the second source gas and the third source gas is in a range of about 1.0:0.1 to about 1.0:1.0.

18. A method of manufacturing a capacitor comprising:
forming the layer structure according to claim 9 on a substrate;
forming a second insulation layer on the first insulation layer;
partially etching the first and the second insulation layers to form a hole through the first and the second insulation layers;
forming a conductive layer on the second insulation layer to fill the hole;
removing the conductive layer on the second insulation layer; and
removing the first and the second insulation layers to form a lower electrode.

19. The method of claim 18, wherein forming the first insulation layer includes:
forming an oxide layer on the substrate; and
doping first impurities including an element in Group III into the oxide layer.

20. The method of claim 18, wherein forming the first insulation layer includes:
forming the oxide layer on the substrate;
doping first impurities including an element in Group III into the oxide layer; and
doping second impurities including an element in Group V into the oxide layer.

21. The method of claim 18, wherein forming the first insulation layer includes forming the first insulation layer using a material having an etching selectivity of about 2:1 to about 5:1 relative to the second insulation layer when an etching solution including hydrogen fluoride (HF) is used for etching the first and the second insulation layers.

22. The method of claim 18, wherein forming the second insulation layer includes forming the second insulation layer using at least one selected from the group consisting of tetraethyl orthosilicate (TEOS), plasma enhanced-tetraethyl orthosilicate (PE-TEOS), high density plasma-chemical vapor deposition (HDP-CVD) oxide, undoped silicate glass (USG) and spin on glass (SOG).

23. The method of claim 18, further comprising:
forming a dielectric layer on the lower electrode and forming an upper electrode on the dielectric layer.

24. The method of claim 18, prior to forming the first insulation layer, further comprising:
forming an etch stop layer on the substrate.

25. A method of manufacturing a semiconductor device comprising:
forming a contact region on a substrate;
forming a conductive structure on the substrate;
forming an insulating interlayer on the conductive structure;
forming a pad through the insulating interlayer, the pad making contact with the contact region;
forming the capacitor according to claim 18 on the pad and the insulating interlayer; and
forming a dielectric layer and an upper electrode on the lower electrode.

26. The method of claim 25, wherein forming the insulating interlayer includes forming an oxide doped with at least one kind of impurities and a flatness of the insulating interlayer fluctuates according to a type and concentration of the impurities.

27. The method of claim 25, wherein forming the first insulation layer includes:
forming an oxide layer on the insulating interlayer; and
doping first impurities including an element in Group III into the oxide layer.

28. The method of claim 25, wherein forming the first insulation layer includes:
forming the oxide layer on the insulating interlayer;
doping first impurities including an element in Group III into the oxide layer; and
doping second impurities including an element in Group V into the oxide layer.

29. The method of claim 25, wherein the oxide layer is formed by supplying a first source gas including an ozone gas and a silane gas onto the insulating interlayer, the first impurities are doped by supplying a second source gas including triethylborate into the oxide layer, and the second impurities are doped by supplying a third source gas including triethylphosphate into the oxide layer.

30. The method of claim 29, wherein a flow rate ratio between the second source gas and the third source gas is in a range of about 1.0:0.1 to about 1.0:5.5.

31. The method of claim 25, wherein the first insulation layer is formed using a material having an etching selectivity of about 2:1 to about 5:1 relative to the second insulation layer when an etching solution including hydrogen fluoride is used for etching the first and the second insulation layers.

32. The method of claim 31, wherein the second insulation layer is formed using at least one selected from the group consisting of TEOS, PE-TEOS, HDP-CVD oxide, USG and SOG.

33. The method of claim 25, before forming the first insulation layer, further comprising:
forming an etch stop layer on the insulating interlayer.
